(19) United States
(12) Patent Application Publication
(10) Pub. No.: US 2002/0041417 A1
(43) Pub. Date: Apr. 11, 2002

(54) Burst mode optical receiver using multi-stage feedback

(76) Inventors: Sub Han, Gyeonggi-do (KR); Man Seop Lee, Daejeon (KR)

Correspondence Address: BACON & THOMAS, PLLC, 4th Floor, 625 Slaters Lane, Alexandria, VA, 22314-1176, US

(21) Appl. No.: 09/825,978

(22) Filed: Apr. 5, 2001

(30) Foreign Application Priority Data
Aug. 23, 2000 (KR) 2000-48975

(51) Int. Cl. H03F 17/00; H04B 10/06

(52) U.S. Cl. 359/189; 330/59

(57) ABSTRACT

A burst mode receiver using a multi-stage feedback reduces its pulse width distortion in output data and improves its sensitivity by exactly extracting a reference voltage used as a detection threshold based on a packet transmission for an optical multi-access network. The receiver comprises a differential preamplifier circuit for generating an output voltage after detecting a difference between a detected current input signal from photodetector and a reference input signal; current source for compensating an offset of the differential preamplifier circuit; multistage amplifier means for adjusting a voltage level of the reference signal to a half value of the output voltage of the differential preamplifier circuit; blocking transistor for responding to an output of the multistage amplifier means; capacitor for storing a peak amplitude of the detected current input signal; and buffer transistor for controlling a discharge rate of the capacitor.

### FIELD OF THE INVENTION

The present invention relates to a high-speed optical data transmission system; and, more particularly, to a burst mode optical receiver using a multi-stage feedback which reduces its pulse width distortion and improve its sensitivity by exactly extracting a reference voltage used as a detection threshold based on a packet transmission for an optical multi-access network.

### BACKGROUND OF THE INVENTION

For multimedia communications, a large data transmission capacity of subscriber networks, such as B-ISDN, is very essential and fiber-optic subscriber systems, such as FTTH(Fiber to the Home), are widely employed in facilitating data communications thereof. A passive optical network(PON) is one of the most promising ways to realize optical subscriber systems. In such a system, TDMA(time division multiple access) is used for a multipoint multiple access. In TDMA, each user packet is multiplexed in a time sequence, thereby causing burst data with various signal amplitudes.

In an optical multi-access network, any node can use a designated time slot to send a packet to some other nodes. A very significant feature of the optical multi-access network that is different from conventional point-to-point links is that respective amplitudes and phases of the received packets can be quite different from packet to packet due to different fiber attenuation and a chromatic dispersion caused by the variation of the transmitters' wavelengths.

A conventional ac-coupled optical receiver is not suitable for burst-mode operation because it cannot instantaneously handle different packets arriving with large difference in optical power and phase alignment. On the other hand, a burst-mode optical receiver, i.e., a high-speed, dc-coupled optical receiver, can adapt to the variation in optical power and phase alignment on a packet-by-packet basis. However, the burst-mode optical receiver, while ideally suited for burst mode operation, is proven difficult to implement because of the necessity of establishing a logic reference voltage V_{REF} level within a few millivolts of the dc center (one-half of the sum of the minimum and maximum excursions of the data signal) of the received data pulse.

When a digital data signal from a data link is received by a preamplifier of a dc-coupled receiver, the signal has been degraded to an analog-type signal with uncertain amplitude and non-zero transition times between the logic ZERO and logic ONE level. Ideally, the dc center of the preamplifier output should match with the logic threshold of the decision circuit so that the decision circuit can restore the analog-type signal to a clean digital signal. When the dc center at the preamplifier output does not match with the logic threshold, the decision circuit causes a pulse-width distortion(PWD) or may not be able to detect a logic transition. This PWD is undesirable because it reduces the sensitivity and maximum bandwidth of the system. The problem is additionally complicated by the fact that input data amplitudes can vary by factors of 100 or more.

Thus it is a longstanding challenge to design a burst mode digital data receiver with minimized PWD and increased sensitivity.

Referring to FIG. 1, there is provided a prior art dc-coupled burst mode receiver for an optical multi-access network. For minimizing the PWD, the prior art dc-coupled burst mode receiver additionally includes a current source I_{ADJ} connected to a resistor Z_{T} and a positive input of transimpedance amplifier 12 in a differential preamplifier unit 10. The current source I_{ADJ} compensates an offset generated from the differential preamplifier unit 10, but doesn't compensate a structural offset generated by a turn-on voltage of respective transistors within a peak detector 20.

Moreover, the offset generated in the peak detector 20 is serious in case of using a compound semiconductor device wherein the turn-on voltage of respective transistors is high. For example, the compound semiconductor device is preferred in a high-speed circuit, but the turn-on voltage of AlGaAS/GaAs HBT transistor is approximately double that of silicon bipolar junction transistor (BJT) and a voltage gain is lowered because a transconductance is low for an identical corrector current. The lowered voltage gain doesn't reduce the offset generated by the turn-on voltage of transistor.

Therefore, it is a problem in the prior art dc-coupled burst mode receiver that sensitivity is very degenerated because the PWD is generated due to the offset of the peak detector 20 to the offset of the peak detector 20 to thereby reduce the maximum transmission speed.

FIG. 2 illustrates the PWD of the output voltage for the receiver of FIG. 1.

The PWDs A and B of the receiver show asymmetry since a reference voltage V_{ref} is not exactly one-half the sum of the minimum and maximum excursions of output voltage of the receiver, i.e.,

$${V}_{ref} = {V}_{O} ( dc ) + \{ {( \frac{G}{1 + G} )}^{2} {I}_{IN} \frac{{Z}_{T}}{2} - \frac{{V}_{BE , 116} + {V}_{BE , 118}}{1 + G} \}$$

$$\begin{matrix}Δ {V}_{O} = {I}_{IN} {Z}_{T} ( \frac{G}{1 + G} ) with pulse present \\ \approx {I}_{IN} {Z}_{T} for G >> 1 \\ Δ {V}_{O} = - {I}_{IN} {Z}_{T} ( \frac{{G}^{2}}{( 1 + G ) ( 2 + G )} ) with pulse absent \\ \approx - {I}_{IN} {Z}_{T} for G >> 1\end{matrix}$$

In case the voltage V_{ref} generated through the peak detector 20 is smaller than

$$\frac{{Z}_{T} {I}_{IN}}{2}$$

for the asymmetry of the device and the structural offset of the circuit, the width and amplitude of a logic ZERO signal decrease and those of a logic ONE signal increase like as the PWD A of the receiver. On the other hand, in case the voltage V_{ref} is larger than

$$\frac{{Z}_{T} {I}_{IN}}{2} ,$$

the width and amplitude of the logic ZERO signal increase and those of the logic ONE signal decrease like as the PWD B of the receiver.

### SUMMARY OF THE INVENTION

It is, therefore, an object of the present invention to provide a burst mode optical receiver using a multi-stage feedback for improving its sensitivity by exactly extracting a reference voltage used as a detection threshold based on a packet transmission for an optical multi-access network.

In accordance with the present invention, there is provided a burst mode optical receiver, comprising:

differential preamplifier circuit for generating an output voltage after detecting a difference between a detected current input signal from photodetector and a reference input signal;

current source for compensating an offset of the differential preamplifier circuit;

multistage amplifier means for adjusting a voltage level of the reference signal to a half value of the output voltage of the differential preamplifier circuit;

blocking transistor for responding to an output of the multistage amplifier means;

capacitor for storing a peak amplitude of the detected current input signal; and

buffer transistor for controlling a discharge rate of the capacitor.

### BRIEF DESCRIPTION OF THE DRAWINGS

The above and other objects and features of the present invention will become apparent from the following description of preferred embodiments given in conjunction with the accompanying drawings, in which:

FIG. 1 shows a prior art dc-coupled burst mode receiver;

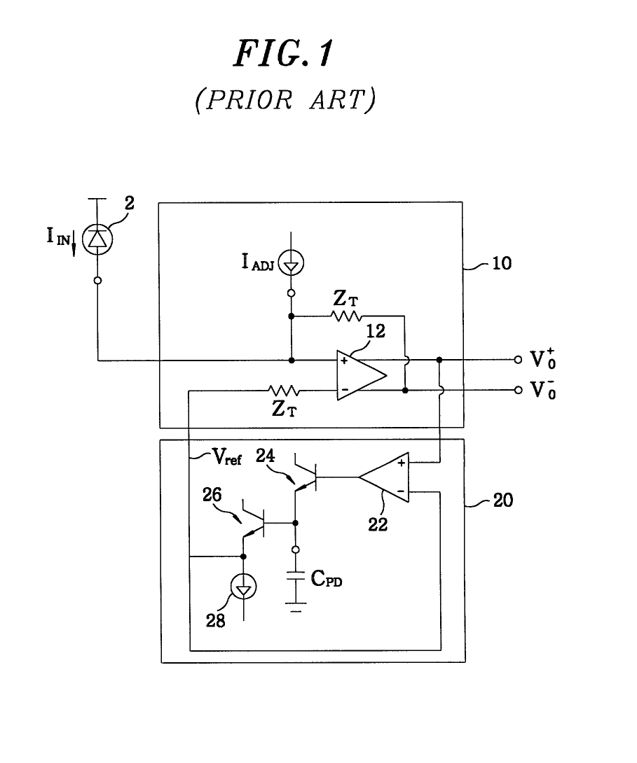

FIG. 2 presents a resulting PWD of an output voltage for the receiver of FIG. 1;

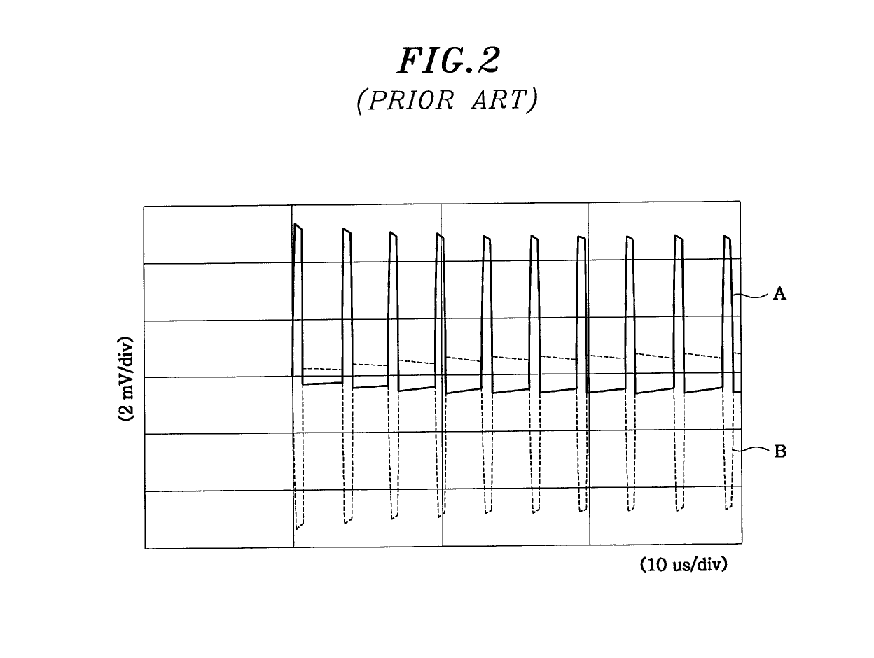

FIG. 3 illustrates a burst mode receiver in accordance with the present invention;

FIG. 4 depicts a resulting PWD of an output voltage for the receiver of FIG.3; and

FIG. 5 provides a detailed specific embodiment of the present invention.

### DETAILED DESCRIPTION OF THE PREFERRED EMBODIMENTS

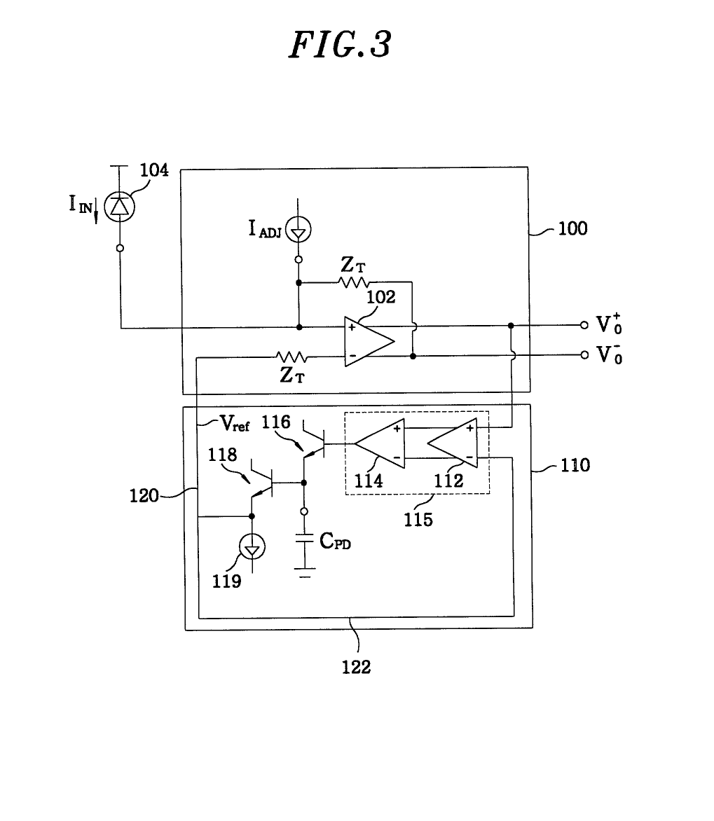

Referring to FIG. 3, there is provided a burst mode optical receiver using a multi-stage feedback in an optical multi-access network in accordance with the present invention, wherein the receiver comprises two circuit units 100 and 110. The first unit 100, i.e., a differential preamplifier unit, includes, illustratively, a well-known differential input/output transimpedance amplifier 102 with a nominal transimpedance value of Z_{T}, as determined by the feedback resistor Z_{T}, and a current source I_{ADJ}. The second unit 110 is a voltage reference circuit, illustratively implemented as a peak detector, for generating a reference voltage V_{ref} that sets a logic threshold voltage for the first unit 100. The peak detector 110 includes a differential amplifier 115 with at least two identical amplifiers 112 and 114, a blocking transistor 116, a peak voltage holding capacitor C_{PD}, a buffer transistor 118 and a bias circuit 119. The number of the identical amplifiers within the differential amplifier 115 is determined by calculating a gain and a power dissipation of the peak detector 110. In the present invention, the peak detector 110 uses the differential amplifier 115 with two identical amplifiers 112 and 114.

A photodetector delivers an optical input current I_{IN} proportional to the optical power input received by photodetector from lightwave signal to the differential preamplifier unit 100. In the differential preamplifier unit 100, I_{IN} is inputted to a positive input lead of the transimpedance amplifier 102 and V_{ref}, i.e., an output of the peak detector 110, is inputted to a negative input lead of the transimpedance amplifier 102. The differential preamplifier unit 100 amplifies a difference between I_{IN} and a detection threshold current transformed through the feedback resistor Z_{T} from V_{ref} to generate output voltages V_{O}⁺ and V_{O}⁻, and adds a current source I_{ADF} connected to the resistor Z_{T} to the positive input of the transimpedance amplifier 102 for compensating an offset generated from itself.

The peak detector 110 has a positive input of the differential amplifier 115 with two identical amplifiers 112 and 114 connected to the positive output lead V_{O}⁺ of the transimpedance amplifier 102 and its output voltage V_{ref} connected to the resistor Z_{T} connected to the negative input of the transimpedance amplifier 102. This connection forms a negative feedback loop for generating a reference dc-voltage on lead 120 from the voltage on lead V_{O}⁺ of the transimpedance amplifier 102. Another feedback loop 122, including the differential amplifier 115 with two identical amplifiers 112 and 114, transistors 116 and 118, and capacitor C_{PD}, controls the voltage gain of the peak detector 110.

The operation of the present invention is best understood by analyzing the differential transfer function of the transimpedance amplifier 102 as a result of the connection of the peak detector 110.

For the transimpedance amplifier 102, the low frequency, differential transfer function is ΔV_{O}=V_{O}⁺−V_{O}⁻=Z_{T}I_{IN}, where I_{IN} is the input current.

The peak detector 110 samples only one of the amplifier 102 outputs, and therefore stores a peak value of the single-ended transfer function,

$$Δ {V}_{O }^{+} = {Z}_{T} \frac{{I}_{IN}}{2}$$

Thus, the V_{ref} with amplitude exactly equal to one-half the peak differential signal swing is generated by the peak detector 110 and applied to the negative input of the transimpedance amplifier 102. Preferred embodiments of the present invention advantageously utilize the inherent signal-splitting characteristic of a differential amplifier, i.e., transimpedance amplifier 102, to develop V_{ref} that scales ideally with an input signal amplitude.

Consider the following sequence of events in order to understand the operation of the circuit better. Suppose that at time t=0, there is no data present and, therefore, I_{IN}=0. The peak detector capacitor C_{PD} is discharged. When the data burst arrives, and under the condition that ΔV_{O}⁺=−ΔV_{O}⁻, the transfer equation for the circuit in FIG. 3 is

$$Δ {V}_{O }^{+} = \frac{{I}_{IN} {Z}_{T}}{2}$$

(Here “Δ” signifies the change in voltage level after arrival of the data burst.) The differential amplifier 115 within the peak detector 110 charges the peak detector capacitor C_{PD} until the voltage at the differential amplifier 115's plus terminal is equalized to that of its minus terminal. Respective turn-on voltage offsets V_{BE,116} and V_{BE,118} in the transistors 116 and 118 are reduced in amplitude by a factor proportional to the open loop gain of the differential amplifier 115. The voltage stored on the peak detector capacitor C_{PD}, proportional to

$$\frac{{I}_{IN} {Z}_{T}}{2} ,$$

is equal to the desired V_{ref}.

Therefore, the peak detector 110 adjusts a level of the reference voltage V_{ref} to one-half the output voltage of the transimpedance amplifier 102 after comparing the output voltage V_{O}⁺ of the transimpedance amplifier 102 with the reference voltage V_{ref}. Especially, turn-on voltage offsets V_{BE,116} and V_{BE,118} are reduced for total increased gain G² through the differential amplifier 115 to reject the PWD of output data.

If V_{offset} of the differential preamplifier unit 100 is ignored for being eliminated through the current source I_{ADJ}, the reference voltage V_{ref} including V_{O}(dc) as the output data for I_{IN} is given as

$${V}_{ref} = {V}_{O}^{+} ( peak ) = {V}_{O} ( dc ) + \frac{G}{2 ( 1 + G )} {I}_{IN} {Z}_{T} \qquad ( 1 )$$

Practically, the peak detector capacitor C_{PD} is not charged by V_{O}⁺(peak) generated from the input current I_{IN} for the turn-on voltage V_{BE,116} of the transistor 116. If the turn-on voltages of the blocking transistor 116 and buffer transistor 118 are V_{BE,116} and V_{BE,118}, respectively, an input voltage of the first amplifier 112 having the gain G is V_{O}⁺(Peak)−V_{ref}. At this time, if the amplifier 102 of the differential preamplifier 100 and the amplifier 112 of the peak detector 110 have the identical gain G, the offsets of the amplifiers are cancelled with each other for connecting the positive terminal and the negative terminal of the amplifiers intercrossly.

Therefore, the reference voltage V_{ref} obtained from the peak detector 110 is given as

V_{ref}=G{V_{O}⁺(peak)−V_{ref}}−(V_{BE,116}+V_{BE,118}) (2)

Referring to the equation (2), V_{O}⁺(peak) obtained from the differential preamplifier 100 corresponds to the maximum output voltage of the differential preamplifier 100 to be inputted to the positive terminal of the first amplifier 112 in the peak detector 110 when a data pulse is present (I_{IN}≠0), i.e.,

$${V}_{O}^{+} ( peak ) = \frac{G}{2 ( 1 + G )} {I}_{IN} {Z}_{T} \qquad ( 3 )$$

Substituting equation (3) for V_{O}⁺(peak) in equation (2) yields

$${V}_{ref} = {V}_{O} ( dc ) + \{ {( \frac{G}{1 + G} )}^{2} {I}_{IN} \frac{{Z}_{T}}{2} - \frac{{V}_{BE , 116} + {V}_{BE , 118}}{1 + G} \} \qquad ( 4 )$$

In equation (4), V_{BE,116} and V_{BE,118} term are reduced by (1+G) through the gain of the amplifier 112, However, in case of the differential amplifier 115 with two identical amplifiers 112 and 114 as FIG. 3, an open-loop gain of the peak detector 110 is G² and V_{BE,116} and V_{BE,118} term are reduced by (1+G²) . Therefore, the sensitivity of the receiver is greatly improved.

Substituting G² and equation (3) for G and V_{O}⁺(peak) respectively in equation (2) yields

$${V}_{ref} = {V}_{O} ( dc ) + \{ ( \frac{{G}^{2}}{1 + {G}^{2}} ) ( \frac{G}{1 + G} ) {I}_{IN} \frac{{Z}_{T}}{2} - \frac{{V}_{BE , 116} + {V}_{BE , 118}}{1 + {G}^{2}} \} \qquad ( 5 )$$

If the differential amplifier with N identical amplifiers is used, the open-loop gain of the peak detector 110 is G^{N}, which will yield

$${V}_{ref} = {V}_{O} ( d c ) + \{ ( \frac{{G}^{N}}{1 + {G}^{N}} ) ( \frac{G}{1 + G} ) \frac{{I}_{IN} {Z}_{T}}{2} - \frac{{V}_{BE , 116} + {V}_{BE , 118}}{1 + {G}^{N}} \} \qquad ( 6 )$$

Referring to equation (6), as N is getting bigger, the offset is getting smaller. However, there is a drawback that as the number of amplifiers increases, more power is dissipated. Therefore, it is desirable that not only G but also power dissipation is taken into consideration for the determination of an optimum N for the sensitivity of the receiver.

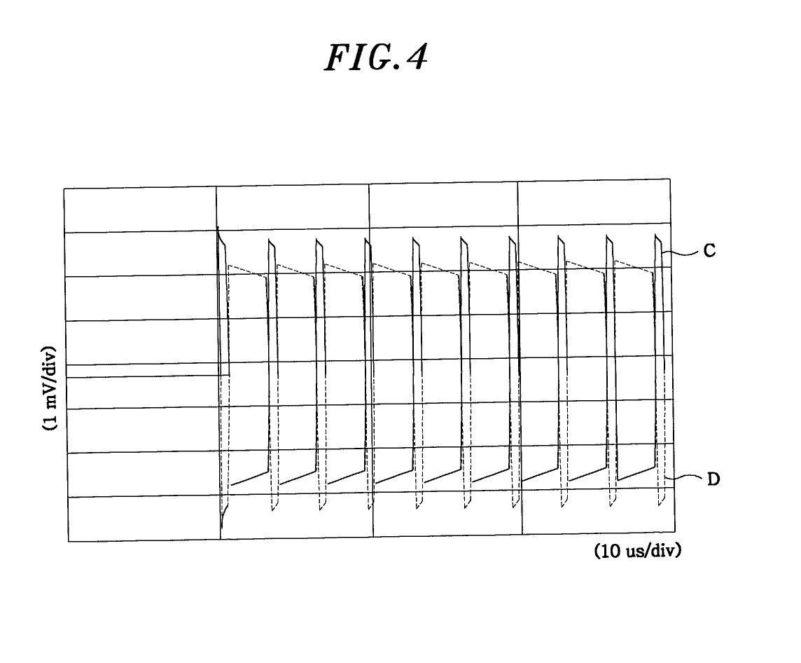

Referring to FIG. 4, there is shown the resulting PWD of the output voltage for the receiver of FIG.3. In the receiver, the offset is compensated through the peak detector 110 and the reference voltage V_{ref}, i.e., the exact detection threshold of output data, is generated. Therefore, the improved sensitivity is obtained because the PWD is reduced and the amplitude of the logic signal is constant in the output data.

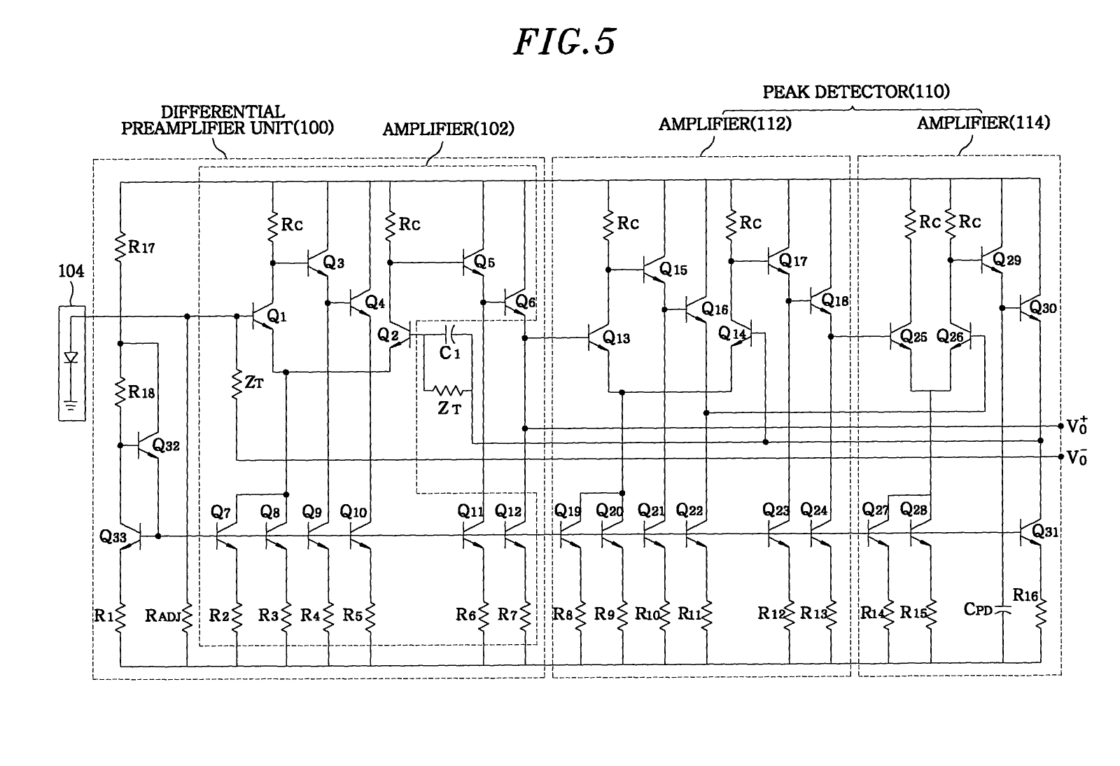

A detailed illustrative schematic diagram of the present invention is shown in FIG. 5. FIG. 5 will be discussed in conjunction with FIG. 3. The amplifier 102 in the differential preamplifier unit 100 has differential pair Q1-Q2; follower/level shifter stages Q3-Q4, Q5-Q6; and current sources Q7-Q12 . Resistors R₂-R₇ are bias current resistors and resistor R_{ADJ} plays a role of compensating the offset generated in the two input terminals of the amplifier 102 by making a current flow into the positive terminal of the amplifier 102. The resistor R_{ADJ} corresponds to the current source I_{ADJ} in FIG. 3.

In the peak detector 110, the first amplifier 112 and the second amplifier 114 include a plurality of transistors Q13-Q24 , Q25-Q31 , respectively. Said plurality of transistors may be categorized into respective differential pairs Q13-Q14 , Q25-Q26 of the first amplifier 112 and the second amplifier 114; follower/level shifter stages Q15-Q16, Q17-Q18 ; and current sources Q19-Q24 , Q27-Q28 and Q31 The transistors 116 and 118 of FIG. 3 are, respectively, transistors Q29 and Q30. The peak detector capacitor C_{PD} is connected between Q29 and Q30 to be charged with the detected peak value.

Each of the first amplifier 112 and the second amplifier 114 has an identical gain G by using the identical bias current and resistor R_{C} to those of the amplifier 102 of the differential preamplifier unit 100. Therefore, the total gain of the differential amplifier with two amplifiers 112 and 114 is G² and the structural offset is reduced by the gain G² through the turn-on voltage of the transistors Q29 and Q30.

While the invention has been shown and described with respect to the preferred embodiments, it will be understood by those skilled in the art that various changes and modifications may be made without departing from the spirit and scope of the invention as defined in the following claims.

What is claimed is:

1. A burst mode optical receiver, comprising:
a differenial preamplifying means for detecting a difference between a digital data input signal and a reference signal to thereby generate an output signal;
a reference signal generating means, including a multistage amplifying and a storing means, for detecting a peak value of the output signal and comparing the output signal with the reference signal through a multistage amplifying means to thereby generate the reference signal corresponding to the peak value of the output signal, and for storing a peak value of the reference signal and providing the reference signal to the differenial preamplifying means and the multistage amplifying means through the storing means.

2. The burst mode optical receiver of claim 1, wherein the differenial preamplifying means includes:
a current source for compensating an offset of the differenial preamplifying means.

3. The burst mode optical receiver of claim 1, wherein the multistage amplifying means includes two or more amplifiers.

4. The burst mode optical receiver of claim 3, wherein the number of the amplifiers is determined by taking both the gain and a power dissipation of the reference signal generating means into consideration.
